(19) United States
(12) Patent Application Publication
(10) Pub. No.: US 2026/0251726 A1
(43) Pub. Date: Aug. 27, 2026

(54) Ground Monitoring Device

(71) Applicant: Steiner Enterprises, Lafayette, IN (US)

(72) Inventors: Thomas P. Hicks, Lafayette, IN (US); Donald E. DeWitt, Syracuse, IN (US); Joshua E. DeWitt, Westfield, IN (US); Christopher R. Laudenschlager, Lafayette, IN (US); Matthew T. Budde, Lafayette, IN (US)

(21) Appl. No.: 19/551,176

(22) Filed: Feb. 26, 2026

Related U.S. Application Data
(60) Provisional application No. 63/764,178, filed on Feb. 27, 2025.

(51) Int. Cl. G01R 31/52; G01R 23/16; G01R 27/02; G01R 31/42

(52) U.S. Cl. CPC G01R 31/52; G01R 23/16; G01R 27/02; G01R 31/42

(57) ABSTRACT

A ground monitoring device connectable to the electrical system of an RV, boat or other vehicle or to a remote or shore AC power supply, is configured to monitor the ground impedance by a direct connection to the AC power supply. In one feature, the ground monitoring device can include the capability to disconnect the electrical system of the vehicle from the AC power supply if the impedance exceeds a predetermined threshold.

### PRIORITY CLAIM

This application is a utility filing from and claims priority to U.S. Provisional Application No. 63/764,178, filed on Feb. 27, 2025, the entire disclosure of which is incorporated herein by reference.

### BACKGROUND

Large vehicles, such as recreational vehicles (RV) and boats, often have A/C devices, such as appliances, as well as an onboard power supply, such as a battery, that require an A/C power inlet. These power inlets are generally configured to receive a large amount of electricity at a relatively high amperage.

The power inlets are often twist-lock connectors. A power cable runs from an RV park pedestal or dock pedestal to the RV or boat, respectively. The power cable is then placed into the power inlet opening, twisted to lock, and sometimes a threaded sealing ring is used to obtain water resistance.

Because many recreational vehicles are mobile, they are used in various locations rather than a single location that is owned or maintained by the owner of the recreational vehicle. As a result, some of the power sources connected to the recreational vehicle may provide power of an unknown quality. In situations where the quality of the power is poor, the recreational vehicle may be damaged or the vehicle owner may be at risk of electrical shock. Additionally, because the power is introduced to the recreational vehicles via the power source is high, the recreational vehicle may be significantly adversely affected if the poor quality of the power source causes damage that is not quickly noticed.

Thus, there exists a need for owners of recreational vehicles and boats to quickly and easily confirm that the high-power source that they connect to via the power inlet is of a proper quality by quick visual inspection. Hughes Autoformers, LLC, provides a range of products to address this need, such as its SV30API product and its U.S. Pat. No. 12,049,146. The Hughes product is a power inlet for use with large vehicles that includes a monitoring module that monitors for error conditions in the electrical service to the power inlet. In particular, the error conditions monitored by the Hughes product includes ground not connected, neutral not connected and improper wiring. The Hughes product illuminates an error indicator light and/or transmits an error signal via a communications module. However, the Hughes monitoring module does not disconnect electrical power to the vehicle.

The Hughes monitoring module uses opto-isolators to detect when voltage is present and provide a signal to a microprocessor that handles the logic to determine which LED indicator lights to illuminate. Thus, this circuit is incapable of measuring ground impedance, line voltages, and ground voltage.

The National Electric Code (NEC) has issued requirements for the electrical equipment of recreational (Section No. 551.40(D)) that requires a ground-fault circuit interrupter at the point where the vehicle power supply assembly terminates within the vehicle for 120V or 120/240V electrical systems. The section also requires a ground monitor interrupter permanently installed between the feeder assembly connection to the vehicle and before either a transfer switch if installed or the panelboard. The interrupter may also need to meet UL2299 (type II GMI) specifications. A GMI device is an electrical safety device that continuously measures and monitors the integrity of a grounding system, and disconnects the electrical system from the A/C power supply and alerts users if a connection to the ground becomes compromised or unsafe.

Monitoring systems, like the Hughes SV30API product, provide one step in monitoring electrical quality for an RV, but fail to meet the new NEC safety requirements. Simply detecting an error condition does not protect the vehicle or the vehicle owner from a faulty electrical connection. There is a need for a monitoring system that not only allows owners of recreational vehicles and boats to quickly and easily confirm that the high-power source that they connect to via the power inlet is of a proper quality by quick visual inspection, but also protects them from a hazardous electrical connection.

### SUMMARY OF THE DISCLOSURE

A ground monitoring device for a vehicle provides an electrical interface between the electrical system of the vehicle and an external AC power supply having L1 and/or L2, ground and neutral lines (depending on the amperage of the system). In one aspect, the device can be a ground monitoring interrupter device that includes components to interrupt the electrical supply upon detection of a ground fault. The ground monitoring interrupter (GMI) device comprises a wire termination module including a contactor connected to the electrical system of the vehicle and a contactor coil that can be energized to close the contactor to electrically connect the device to the electrical system of the vehicle and de-energized to open the contactor to interrupt the electrical connection to the electrical system of the vehicle. A housing includes an electrical power receptacle connected to the contactor and configured to engage a power cable connected to the external AC power supply, and a printed circuit board (PCB) that includes a ground impedance measurement circuitry, contactor control circuitry and a microprocessor control unit (MCU).

The ground monitoring device and the GMI device include ground impedance measurement circuitry that is connected to the AC ground line and the AC neutral line, and that includes a first circuit to apply an AC signal to the AC ground line controlled by the MCU and a second circuit to compare the electrical signal in the AC ground line with the electrical signal in the AC neutral line in which the output of the second circuit is provided to the MCU. For the GMI device, the contactor control circuitry is connected to the contactor coil and is configured to energize the contactor coil only upon receipt of a contactor control signal from the MCU and to de-energize the contactor coil when the contactor control signal is not received. The MCU compares the output of the second circuit to a predetermined impedance value indicative of a desired ground impedance, and generates the contactor control signal only if the output of the second circuit is below the predetermined value.

### BRIEF DESCRIPTION OF THE DRAWINGS

FIGS. 1A-1C are front perspective, front and side views of a ground monitoring interrupter device according to one embodiment of the disclosure, with the device in a closed configuration.

FIGS. 2A-2C are front perspective, front and side views of the ground monitoring interrupter device shown in FIGS. 1A-1C, with the device in an open configuration.

FIG. 3 is an exploded view of the housing of the ground monitoring interrupter device shown in FIGS. 1A-1C.

FIG. 4 is a circuit diagram of line voltage measurement circuitry of the ground monitoring interrupter device of the present disclosure according to one embodiment.

FIG. 5 is a circuit diagram of voltage measurement circuitry of the ground monitoring interrupter device of the present disclosure according to an alternative embodiment.

FIG. 6 is circuit diagram of circuitry for measuring ground impedance according to one embodiment of the present disclosure.

FIG. 7 is circuit diagram of circuitry for measuring ground impedance, including a circuit for applying a sine wave signal to the AC ground line, according to an alternative embodiment of the present disclosure.

FIG. 8 is a circuit diagram of circuitry for measuring ground voltage.

FIG. 9 is a circuit diagram of alternative circuitry for applying a sine wave signal to the AC ground line for use with the ground impedance circuitry of FIG. 7

FIG. 10 is a graph of a composite waveform used by the circuitry for measuring ground impedance shown in FIG. 7.

FIG. 11 is a circuit diagram of circuitry for applying a sine wave signal to the AC ground line according to an alternative embodiment of the present disclosure.

FIG. 12 is a circuit diagram of circuitry for measuring ground impedance using the signal from the circuitry of FIG. 11, according to a further embodiment of the present disclosure.

FIG. 13 is circuit diagram of power input circuitry of the ground monitoring interrupter device of the present disclosure

FIG. 14 is circuit diagram of contactor control circuitry of the ground monitoring interrupter device of the present disclosure.

FIG. 15 is circuit diagram of contactor control circuitry of the ground monitoring interrupter device according to an alternative embodiment.

FIG. 16 is a schematic of the microcontroller according to one embodiment of the disclosure, for use with the circuitry of FIGS. 4-9, 11-15, with the input and output pins identified.

FIG. 17 is a circuit diagram of a ground isolation circuit for use in conducting a hi-pot (high potential) test for the ground monitoring interrupter device of the present disclosure.

FIG. 18 is a perspective view of an inductive power device for use in performing hi-pot testing on the GMI device disclosed herein.

FIG. 19 is a circuit diagram of a power control circuit for the hi-pot power device shown in FIG. 18.

FIGS. 20A and 20B are a perspective view and an exploded view of a hand-held ground monitoring device according to one embodiment of the present disclosure.

### DETAILED DESCRIPTION

A ground monitoring interrupter (GMI) device is provided that will meet all the requirements for a Type I or Type II GMI according to UL and NEC standards. This will include, but is not limited to, the ability to continuously monitor the impedance of the ground to neutral connection, check the ground to neutral voltage, check for miswiring or bad connections, display the status of shore power to the user, detect brown-out voltages, and disconnect power if an issue is detected. The device can have an external device to open/close the main circuit of the vehicle, or can be integrated into the main electrical system of the vehicle.

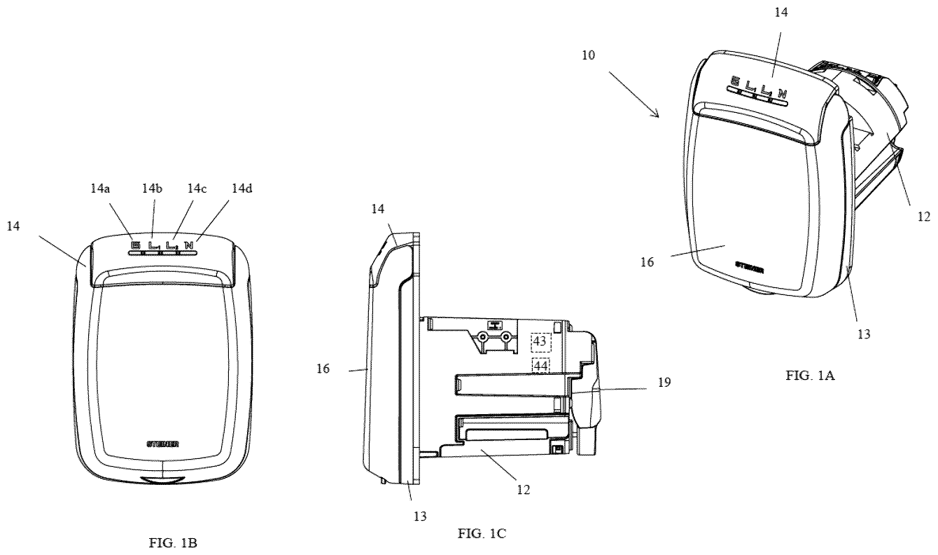

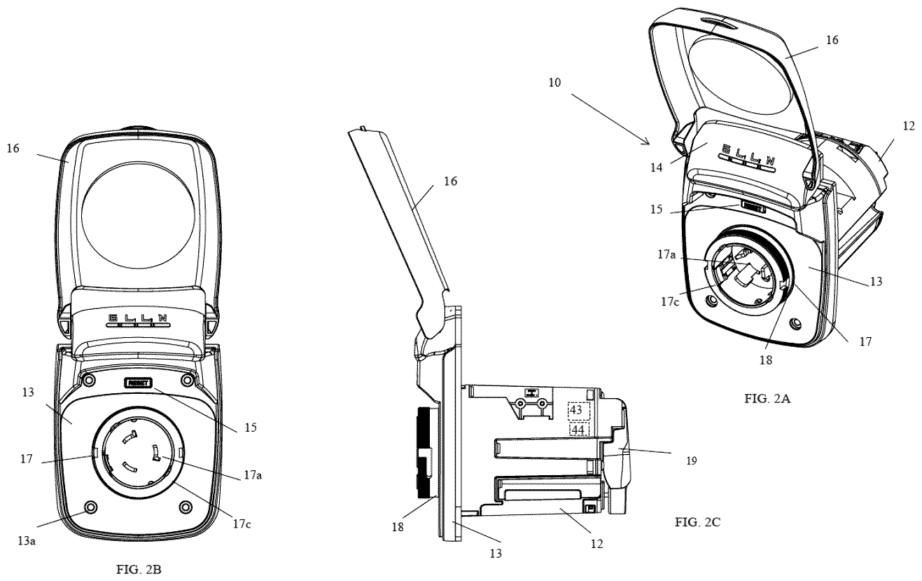

As shown in FIGS. 1A-1C, a ground monitoring interrupter device 10 is provided that includes a wire termination module 12 that includes circuitry and hardware to connect to the main circuitry of the RV, boat or other vehicle. The wire termination module 12 can include a conventional contactor 43 and contactor coil 44 that can be energized to complete the electrical interface between the device 10 and the electrical system of the vehicle. As is known in the art, when the contactor coil is deactivated, no electrical power passes to the vehicle, and conversely the vehicle electrical system is connected to the remote AC power supply when the contactor coil is energized. Other connection devices are contemplated, such as a normally-closed contactor and a relay. The wire termination module can include components for hard-wiring the device with the vehicle circuitry, or components that allow for add-on engagement to the vehicle wiring. A housing 13 is connected to the wire termination module 12 that includes an indicator array 14, a reset button 15 (FIG. 2A-2B) and a movable cover 16. The wire termination module 12 can incorporate a strain relief connection 19 for connection to the existing wiring circuit of the RV, boat or other vehicle.

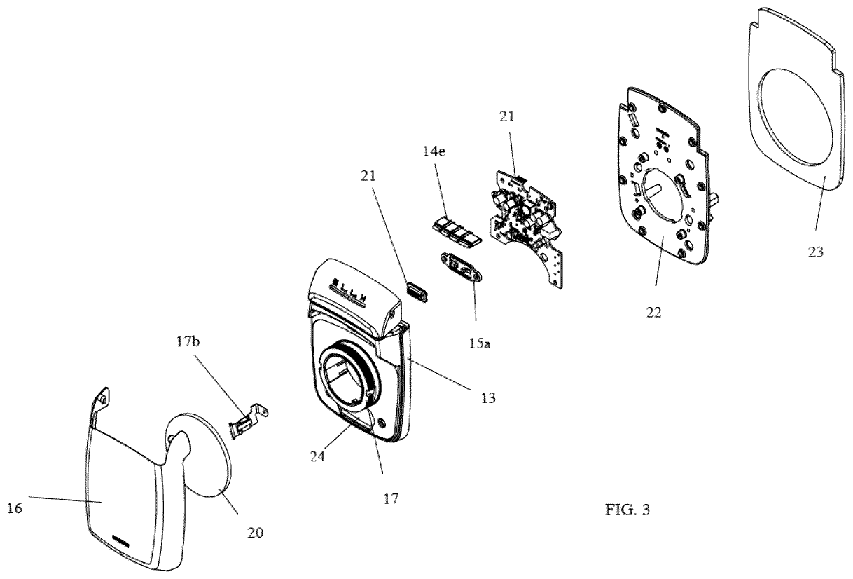

The ground monitoring interrupter device 10 is shown in FIGS. 2A-2C with the cover 16 in its open position. It can be appreciated that the cover 16 is pivotably mounted to the housing 13 and that the cover is configured to provide a substantially weather-proof seal with the housing 13. The cover and housing may include a seal arrangement and positive engagement feature to provide a weather-proof lock between the cover and the housing. The housing 13 can include mounting holes 13a for hard-mounting the device to the wall of the vehicle. Alternatively, the housing can be configured as an adapter that can be plugged into an existing shore power receptacle of the vehicle. In that alternative, the wire termination module can be configured to include a NEMA connector or the like. In the illustrated embodiment, the housing 13 includes an electrical power receptacle 17 connected to the contactor in the wire termination module 12. The receptacle includes a connector array 17a configured for electrical connection to a cable connected to the remote or shore power supply. In one embodiment, the connector array 17a can be a NEMA connector, or other connector configured to engage the remote or shore power supply cable, and can include a separate ground terminal 17b (FIG. 3). The connector array 17a includes contacts for direct electrical connection to L1 and/or L2, Ground and Neutral lines. The receptacle 17 can include a threaded connection 18 for a secure and weather-proof engagement of the external power cable with the power receptacle 17 of the ground monitoring interrupter device 10.

A compressible seal 20 (FIG. 3) can be affixed to the inside of the cover 16 in alignment with the rim 17c of the receptacle 17. The seal engages the rim 17c to provide a water-tight seal for the electrical contacts 17a, 17b in the receptacle. In one embodiment the seal 20 is a foam disc.

The indicator array 14 illuminates LEDs that are indicative of a specific electrical fault condition. For instance, the first LED 14a is configured as a “G” to indicate that the ground fault impedance is below the desired threshold. LEDs 14b, 14c are configured as “L1” and “L2”, respectively, to indicate a fault in the line voltage for one of the input lines. (It is understood that this configuration can be modified for a lower amperage system that only includes L1, N and GND lines). LED 14d is configured as an “N” to indicate a fault in the neutral input of the power supply. The LEDs are part of light pipe 14e (FIG. 3) that is mounted to a printed circuit board (PCB) 21 contained within the housing 13. The PCB includes contacts for connection to the contactor 43 in the wire termination module 12. The reset button 15 is supported by a button finger 15a that is also mounted to the PCB 21. The PCB 21 is supported on a back plate 22 that is mounted within the housing 13. A sealing gasket 237 can be provided on the back face of the plate 22 at the interface with the wire termination module 12.

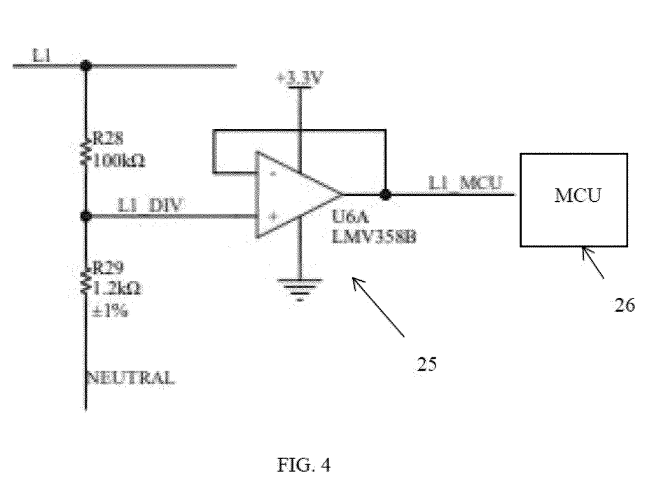

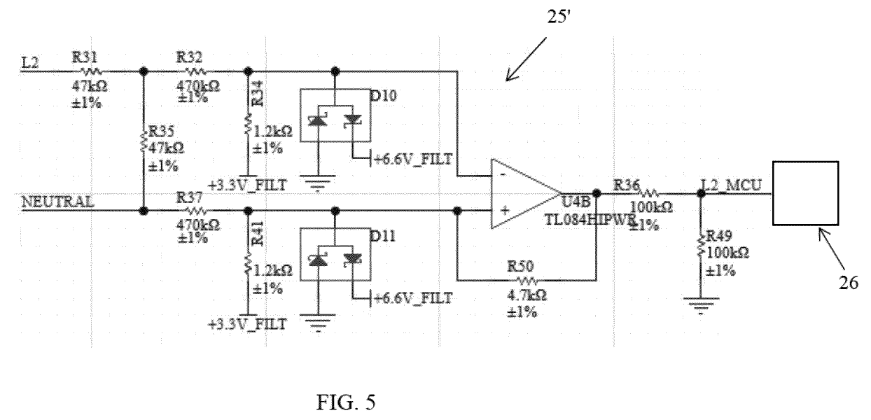

The PCB 21 includes the circuitry and microprocessor control unit (MCU) 26 for monitoring and evaluating the input electrical power at the power receptacle 17. Instead of using optical isolators, such as in the Hughes system described above, the power receptacle of the ground monitoring interrupter device 10 of the present disclosure provides a direct electrical connection between the PCB and the L1 and/or L2 inputs, GND input and Neutral input. A voltage divider is used to measure the input line voltages. Knowing the actual voltage applied to the inputs can be used to determine proper wiring and for brown-out detection if the measured voltage falls below a predetermined value. The line voltage measurement circuitry 25 of one embodiment of the present device 10 is shown in FIG. 4. It is understood that this circuitry can be embodied as hardware but is preferably incorporated into the PCB 21. The circuitry receives the line voltage, such as L1, of the power supply and generates a signal L1_MCU that is provided to a microprocessor control unit (MCU) 26 that is configured to evaluate the incoming voltage and use that information to determine a brown-out or a fault condition in the power signal provided to the RV by comparing the measured voltage to predetermined voltage limits. If the differential comparator of the circuit 25 determines that the line voltage L1 has fallen below a minimum threshold, such as 120V, as reflected by the value of the output signal L1_MCU, the MCU 26 can activate one of the indicator LEDs 14, namely the LED 14b. A similar circuit is connected to the line voltage L2 of a split-phase power supply to provide an output signal L2_MCU to the MCU 26. The MCU 26 can evaluate the L2 signal and activate the indicator LED 14c if there is an error in that line voltage. An alternative circuit 25′ is shown in FIG. 5 that implements the same differential comparator concept. The circuit 25′ incorporates noise filters on the line voltage and neutral inputs from the split-phase power supply. The circuit 25′ is also connected to line voltage L2 and to the AC Ground to provide a measurement of the Ground to Neutral voltage for use in the ground monitor interrupter (GMI) function of the device 10.

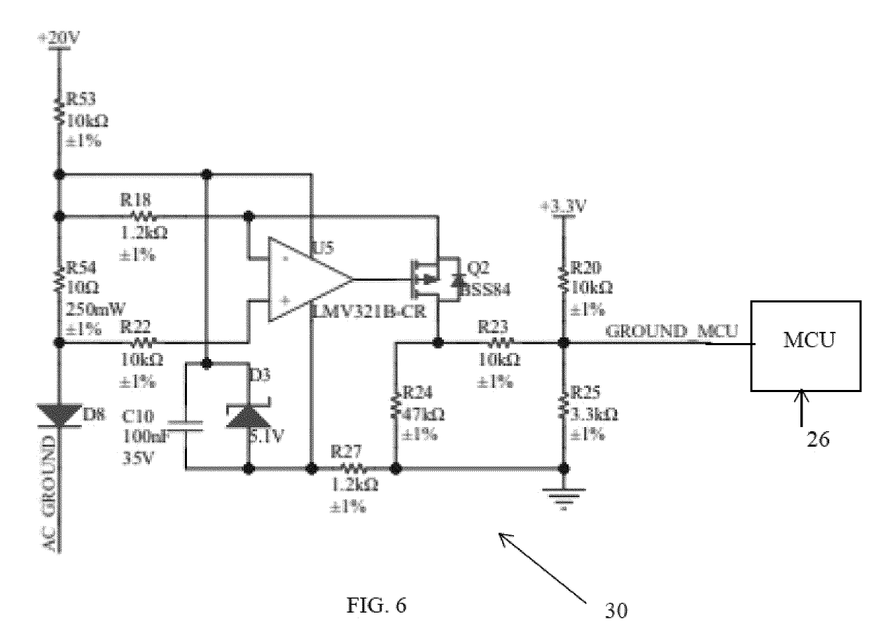

The PCB 21 of the device 10 further includes ground impedance measurement circuitry 30, shown in FIG. 6, that is configured to measure and evaluate the impedance of the ground of the input electrical power at the power receptacle 17. To measure the ground's impedance, a small current is forced to the AC ground line of the power supply. This current is then measured and read into the MCU 26 as signal GROUND_MCU using the circuitry 30 shown in FIG. 6. The MCU 26 is configured to determine the impedance of the line and if it is below a set threshold that is programmed into the MCU. The maximum impedance value can be changed digitally through firmware updates or in an analog fashion using a dipswitch, potentiometer or similar method. In one embodiment, the minimum threshold for a proper ground impedance is 25 ohms, so the MCU compares the signal GROUND_MCU with a stored value indicative of the minimum impedance value. If the impedance falls below that minimum, the MCU activates one of the LED indicators 14, namely the first indicator 14a. Moreover, the MCU 26 is configured to terminate power to the vehicle in the event of a failure of the AC ground from the power supply, as described below. In that respect, the MCU is programmed to conduct the ground fault check at predetermined intervals. The intervals can be different, such as providing shorter intervals when the device is initially connected to an external AC power supply, and longer intervals when power has been continuously supplied for a certain time period. The longer time intervals also prevent false tripping that might occur when another device is plugged into the common AC supply, particularly if the electrical system of the extra vehicle has its own wiring problems. In one embodiment, the initial shorter intervals are every 50 ms, with the ground fault checks at these intervals occurring for the first 1-2 sec after the device has been connected to the vehicle. If the ground fault checks are clean after this first time period, the MCU adopts the longer interval for ground fault checks, such as every 150 ms. The ground fault checks continue as long as the device 10 is connected between the vehicle electrical system and the common AC supply.

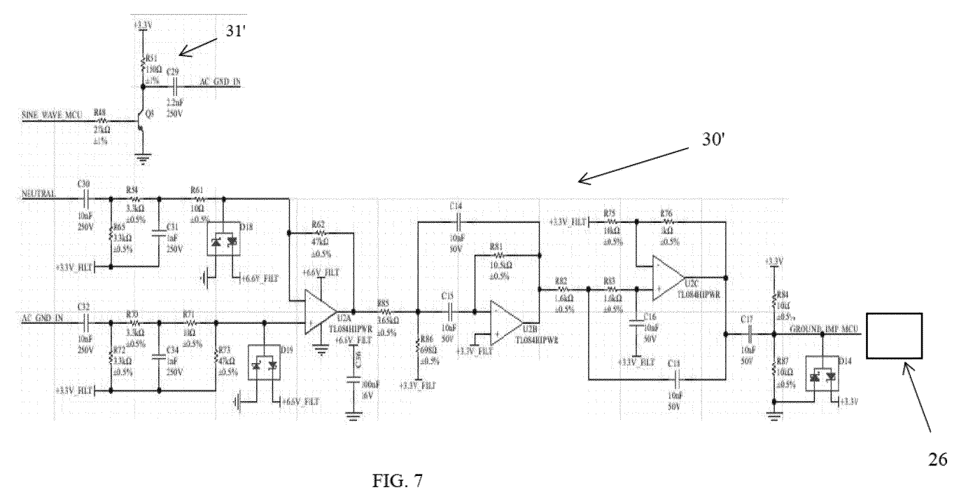

In another embodiment, the ground impedance measurement circuit 30′ shown in FIG. 7 includes circuitry 31′ that applies a small (1 Hz and above) AC signal SINE_WAVE_MCU to the input ground line AC_GND_IN in the circuitry 30′. The measured ground line signal is compared to the neutral line's signal of the input electrical power at the power receptacle 17. The ground and neutral signals are filtered to eliminate noise and amplified so that the signals can be measured more accurately. The MCU 26 can determine the impedance of the ground line based on the output GROUND_IMP_MCU of the circuit 30′. As with the circuitry 30 of FIG. 6, the MCU 26 can be programmed with an impedance threshold value that is compared to the GROUND_IMP_MCU signal from the circuitry 30′.

In one embodiment, the AC signal SINE_WAVE_MCU is generated by a digital-to-analog converter (DAC) that uses a pre-determined table of digital values provided by the MCU 26 that produce a smooth sine wave at a pre-determined frequency. The rate at which the MCU cycles through the pre-determined table of values determines the frequency of the output SINE_WAVE_MCU that is applied to the AC ground input line. The MCU 26 further includes an analog-to-digital converter (ADC) that accepts the analog signal GROUND_IMP_MCU from the differential voltage filter circuit and converts it to a digital value for comparison with the stored impedance threshold value.

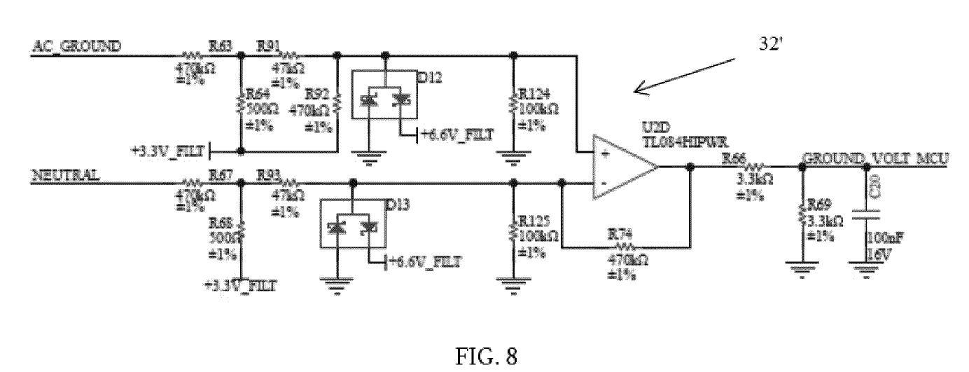

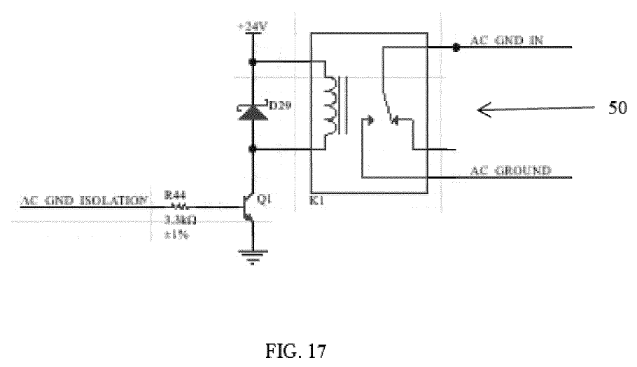

The ground voltage is determined using the circuitry 32′ shown in FIG. 8. The signal GROUND_VOLT_MCU is provided to the microcontroller 26 with the GROUND_IMP_MCU signal generated by the impedance measurement circuitry 30′ of FIG. 7. The input and output pins of one embodiment of the MCU is shown in FIG. 16.

It is common for the RV, boat or other vehicle to connect to a remote or shore AC power supply that is being used by other vehicles. For instance, in an RV camp or a community dock, a single AC source can include four or more outlets to be accessed by vehicles. If there are multiple vehicles connected to a common power supply, the generated signal SINE_WAVE_MCU applied to the ground line will be read by the ground monitoring interrupter devices 10 integrated in the electrical systems of all of the vehicles. Each device 10 in each vehicle connected to the common power supply affects the performance of the circuitry 30′ of those devices. One solution to this problem is to ensure that every device 10 is generating the SINE_WAVE_MCU signal at a unique frequency. This means that every new device would need to have a unique frequency programmed at the factory or that devices are programmed with one of a limited number of unique frequencies and include the ability to communicate with each other to avoid frequency collision.

Another option is to have every device 10 generate a table of given frequencies (which are the same for every device) in a unique order. Then each device generates and detects a specific frequency for a given amount of time. Once the time has expired, that device moves on to the next frequency. With this method, it is very likely that frequency collisions will occur but only for a portion of the time. After gathering data across the complete list of frequencies, some statistical analysis (likely standard deviation and/or median filtering) can be performed to rule out collided data giving each device some data that is valid. With this method, randomness is good so to add to that, the amount of time that a device holds each frequency can be varied based on an unique number, such as the number of times a device has been powered. According to some calculations, if the frequency list contains 25 frequencies and the MCU can maintain a frequency for 1 ms-5 ms (incrementing by 0.005ms) with 12 GMI's all on the same line, then each device will typically be generating a unique frequency about 62% of the time. This value can be increased by increasing the hold time range for each frequency or by increasing the number of frequencies in the list.

In some cases low frequency (60 Hz) noise from ground leakage of electrical devices or other vehicles connected to the same power supply can generate harmonics that leak into the of the device 10, and particularly into the ground impedance measurement circuits 30, 30′, 30″, 30″′. To avoid this interference, the frequency table can include frequencies set to each half harmonic in the 1-2 kHz range (i.e., 1050, 1110, 1170, 1230, 1290, 1350, 1410, 1470, 1530, 1590, 1650, 1710, 1770, 1830, 1890 Hz). In one aspect, a bin spacing can be defined that can help prevent or reduce spectral leakage from neighboring harmonics. This, in one specific embodiment a bin spacing of 30 Hz can be provided to reduce the spectral leakage from the whole number harmonics of 60 Hz. As a further deterrent to spectral leakage, the MCU of the device also measures each of the harmonics of 60 Hz surrounding a frequency selected from the table. For example, when measuring 1590 Hz, the frequencies 1560 Hz and 1620 Hz are also measured, put through the same Goertzel filter, averaged, and then subtracted from the magnitude of 1590 Hz.

When the device 10 is connected to a power supply common to other GMI devices for other vehicles, each device evaluates all of the frequencies in the frequency table—15 in the illustrated embodiment. In order to meet the requirements of UL2299, a GMI must disable the output of the device within 250 ms after detection of a ground impedance of 250 Ohm. In order to ensure that all frequencies in the table can be surveyed by the device, the MCU splits the frequency table into two sections and evaluates both sections simultaneously. In the illustrated embodiment, the table is split into one table of eight frequencies and another of seven frequencies. Each table is cycled through continuously by the MCU of each device and calculations are updated at predetermined intervals, such as every 33 ms in the illustrated embodiment. As mentioned above, the original table of frequencies is scrambled based on the unique ID of the MCU of each device. So each device will have its own unique table order, or sequence of frequencies, to perform, which essentially prevent device collisions between devices 10 connected to a common power supply.

According to another approach to avoid this problem, the MCU 26 of each ground monitoring interrupter device 10 incorporates firmware that will adjust the output frequency of the SINE_WAVE_MCU signal based on the activity of the ground line. On power up, the MCU 26 checks a span of frequencies to determine which is best to use given the line activity. For example, if there are three devices on the same power line (device A is running at 6 kHz, device B at 5 kHz, and device C at 7.5 kHz) and then an additional device D is plugged in, the MCU 26 of device D will see the frequencies that are taken and decide to use 7 kHz as its generated frequency. Device D will then begin to generate a 7 kHz signal. Once the values GROUND_IMP_MCU are read into the ADC of the MCU, the values are put through a FFT (Fast Fourier Transform) or a Goertzel filter function that will determine the magnitude of a given frequency which will be used to calculate the impedance. In an alternative embodiment, each device 10 can produce desired its frequency for a period of time (e.g., 25 ms), obtain the impedance measurement, and then idle for another amount of time (e.g., 75 ms). During the idle time, another device 10 can use that same frequency to obtain its respective impedance measurement. This feature allows several devices to share the same frequency increasing the amount of devices that can be connected to the same remote or shore AC power supply.

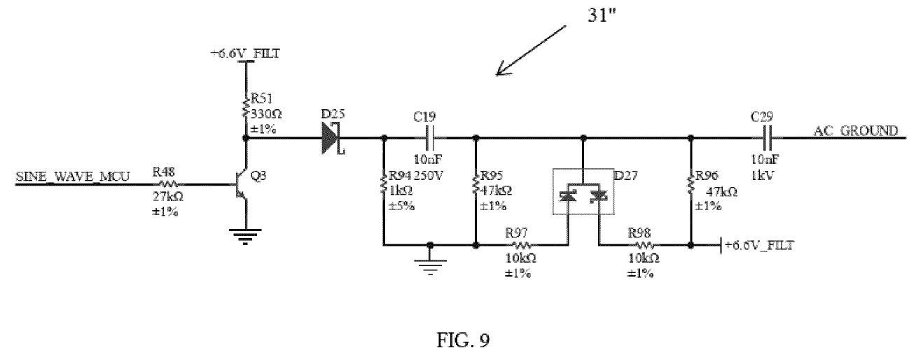

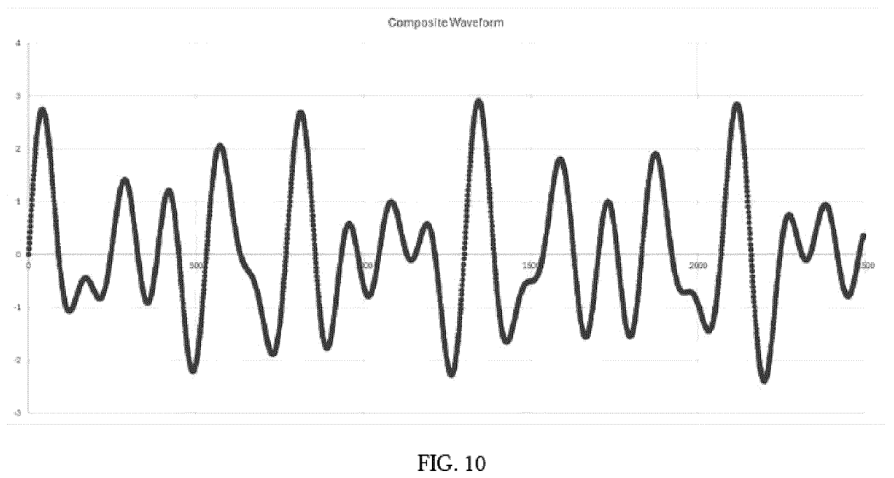

In another embodiment, the MCU produces a composite waveform generated by the summation of three sine waves at given frequencies that is applied to the GND line using the circuitry 31″ shown in FIG. 9. The DAC of the MCU uses the pre-determined table of values to calculate the composite waveforms. A set variable in firmware determines which three frequencies are to be generated. In one specific embodiment, the set variable determines a lowest frequency to be used as a base frequency for one sine wave. The frequencies of the other two sine waves are determined by multiplying the base frequency by constants that are predetermined for and can be unique to each ground monitoring interrupter device 10. For example, the base frequency f1 can be 2 kHz and the unique constants can be 1.37 and 1.96, so that the second frequency f2 will be 2×1.37=2.74 kHz and the third frequency f3 will be 2×1.96=3.92 kHz, resulting in the composite waveform shown in FIG. 10.

The composite waveform is applied to the ground line (GND) and is then put through a filter and differential amplifier circuit between the GND and Neutral lines, as shown in FIG. 7. One advantage of using a composite waveform, rather than a single sine wave, is that each component of the ground line impedance (resistance, capacitance and inductance) can be measured, which can be helpful if an inductive load, such as a motor, is connected to the A/C supply. The measured resistance of the GND to Neutral will not change significantly when the inductive load is added, but the measured impedance can change depending upon the intensity of the load. Being able to extract the actual resistance from the overall measured impedance can avoid false trips of the device 10. The generated signal SINE WAVE MCU and the measured signal GOUND IMP MCU generated by the circuits in FIGS. 7 and 9 are provided to the MCU which implements a lock-in amplification or lock-in detection method by multiplying the digitized values of the two signals for each frequency. These products for each frequency can be used to solve for the actual resistance in the ground line using the equation |Z|=\sqrt{R²+(X_{L}−X_{c})²}, where Z is the total impedance common to all frequencies, R is the actual resistance, X_{c} is the capacitance component 1/jωC for each frequency and X_{L} is the inductance component jωL for each frequency. The calculated value for the actual resistance R can be compared to the resistance threshold to determine if a ground fault condition exists.

As a further alternative, the ground monitoring interrupter device 10 can have the ability to communicate at a higher frequency on the ground and neutral lines. This communication protocol can be used to communicate between multiple devices 10 powered on at the same time, which, in turn, will help each device decide which frequency to use. Additionally, there could be another high frequency for the devices to use to synchronize, which will help with the frequency sharing between devices. When multiple devices are sharing the same frequency, the high frequency clock pulse will determine which device(s) are to run.

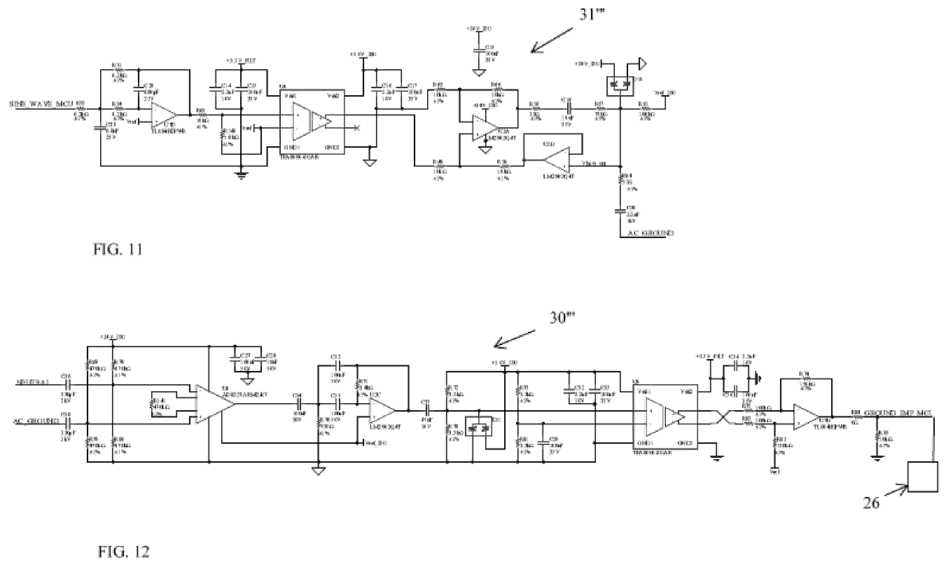

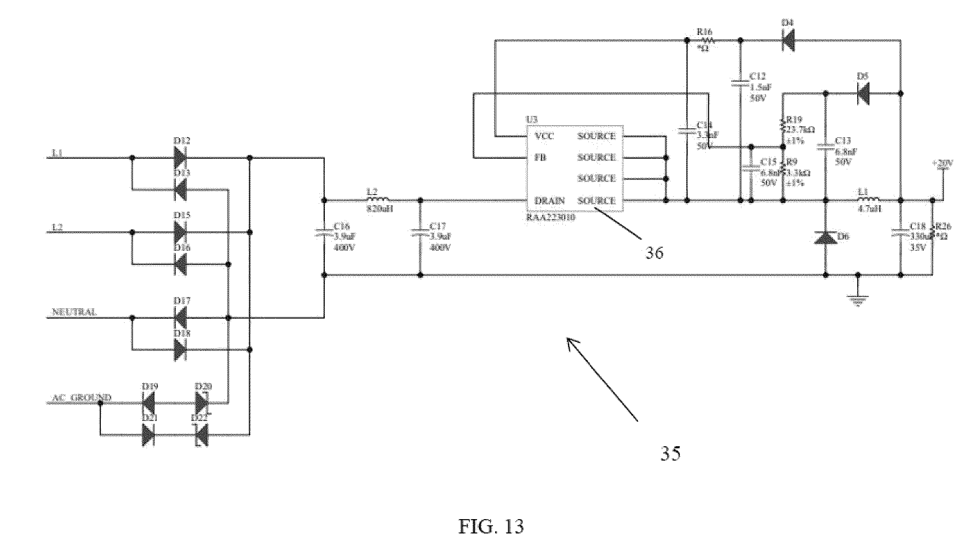

In an alternative embodiment, the MCU generated composite waveform SINE_WAVE_MCU can be applied to the GND line using the circuitry 31′″ shown in FIG. 11. The signal from the MCU is passed through an active low-pass filter (U7D), then through an isolated op-amp (U4) that bridges the gap between the line voltages and the digital voltages. The output from the op-amp is fed to a Howland current pump that injects a consistent current into the AC ground line that resembles the signal provided by the MCU. This output is intended to go through the ground to neutral connection (FIG. 12) and then measured. One benefit of the impedance measurement circuit 30″′ is that it can handle an improperly wired input safely and without damage to the device 10.

This AC GROUND signal from the circuit 31″′ is fed to the circuit 30″′ of FIG. 12, where the injected sine wave signal travels through the ground line, through the neutral connection, and appears at the neutral line. The measurement circuit 30″′ then determines the difference between the signals on the ground and neutral lines, and filters out high frequency noise using an active high-pass filter. The filtered difference signal is fed to an isolated op-amp (U9), with the amplitude of the output from the op-amp being proportional to the impedance between ground and neutral. The signal GROUND_IMP_MCU is fed to the MCU 26 which calculates the impedance and determines if it is below the set threshold that is programmed into the MCU, as described above.

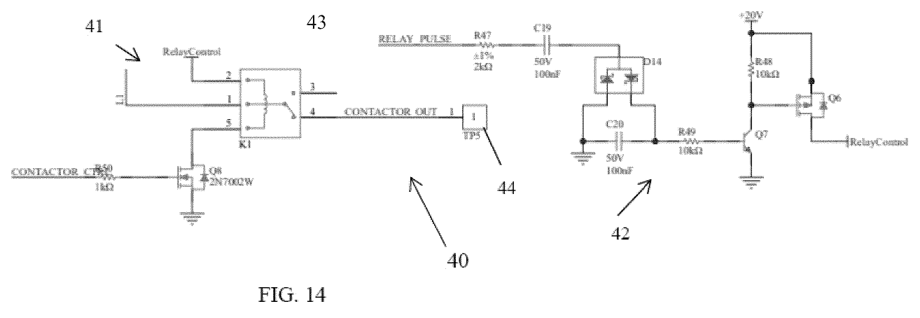

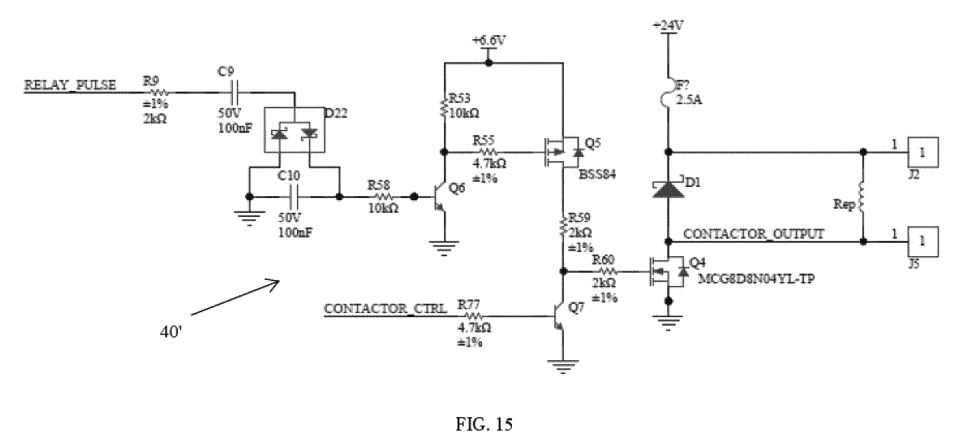

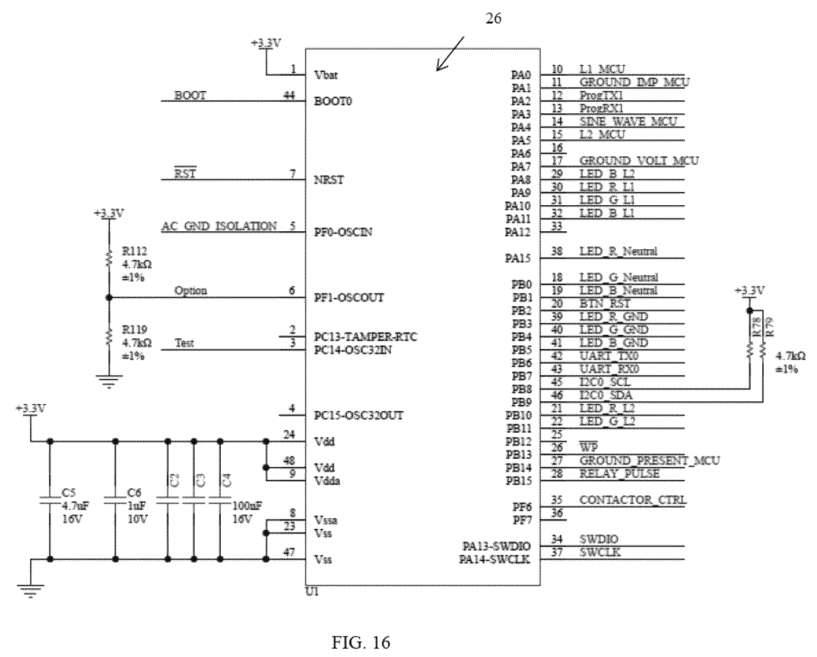

When providing power from a remote or shore AC power supply, there are over 200 possibilities of interchanging wires and missing connections. For instance, the vehicle electrical system wires can be mis-wired relative to the lines of the power supply, such as when the vehicle neutral and ground lines are connected to the power supply ground and neutral lines, respectively. Some wiring connections can be missing, such as a missing connection to phase line L1. The ground monitoring interrupter device 10 is configured to be powered with the least number of connections possible (2) in any orientation that will allow the interrupter device to determine the presence of ground faults. The device thus includes the power input circuitry 35 shown in FIG. 13, connected to the connector array 17a (FIGS. 2A, 2B), that includes an array of diodes D12-D22 at the input of the circuit and that feeds the input signal through an AC/DC buck regulator 36 to supplied to the AC input to other circuitry of the device. The AC power supply L1, L2 and neutral lines include diode pairs and the AC ground line include two diode pairs that allow the power input circuitry 35 to supply AC power to the device only, even if the wiring is incorrect. The circuit 35 can also be configured to measure the current of the hot line(s) (L1, L2) of the power supply when a proper electrical connection to the vehicle electrical system is established, which can then be used by the MCU 26 to measure power consumption, determine if the vehicle is drawing too much current and/or verify if the disconnect circuit 40, 40′ (FIGS. 14-15) is working properly.

The MCU 26 controls whether the electrical signal from the power supply connector array 17a (FIG. 2A) is provided to the vehicle electrical system by way of the contactor control circuitry 40 shown in FIG. 14. The circuitry 40 can be connected to one phase of the AC input power, such as L1. The contactor control circuitry 40 includes a contactor circuit 41 that is connected to the power input L1 and passes the power through the contactor 43 as an output CONTACTOR_OUT_1 to the contactor coil 44 in the wire termination module 12 that is connected to the vehicle electrical system. The contactor control circuit 41 receives two inputs generated by the MCU 26, namely a CONTACTOR_CTRL signal and a RELAY_CONTROL signal. The CONTACTOR_CTRL is generated directly by the MCU, while the RELAY_CONTROL signal is generated by a relay circuit 42 based on a RELAY_PULSE signal generated by the MCU. Two conditions must be met for the signal CONTACTOR_OUT_1 signal to be provided to the contactor coil 44, namely that the CONTACTOR_CTRL voltage signal is high (such as 3.3V) and the RELAY_PULSE signal is toggling at a specified frequency, such as about 1 kH. The RELAY_PULSE signal acts as a safety in the event the MCU malfunctions or is destroyed, or some other undesirable event occurs. As long as the MCU 26 is generating the RELAY_PULSE signal at the proper frequency, the relay circuit 42 will produce the RELAY_CONTROL signal. The contactor is intended to be normally open so that no power passes through the device 10 unless and until the remote or shore AC power passes all checks conducted by the circuitry 25/25′ and 30/30′. In the event that the power fails any check while power is supplied to the vehicle electrical system, the MCU 26 of the device will de-activate the contactor coil 44 and disconnect the vehicle by switching the relay K1 (FIG. 14) from output 4 CONTACTOR_OUT_1 to the null output 3. This deactivation occurs when the CONTACTOR_CTRL is changed from high to low by the MCU.

The alternative contactor control circuitry 40′ shown in FIG. 15 combines the contactor and relay circuits and eliminates the relay K1. The operation of the contactor control circuitry 40′ is otherwise the same as circuitry 40, namely that the MCU 26 generates the RELAY_PULSE and CONTACTOR CTRL signals that determine whether the CONTACTOR_OUTPUT is provided to the contactor coil 44 in the wire termination module 12.

The contactor of the device 10 is normally open. When the device is connected to the external power supply or shore power, the MCU performs the checks on the incoming power and only allows the contactor to be closed if the power passes all of the checks. When the device 10 triggers from an unsafe event, the device will hold its state (i.e., de-energized contactor coil, thereby disconnecting the vehicle system from the line input) until the reset button 15 is pressed. In the reset condition, the MCU verifies that all of the unsafe conditions have been corrected and then directs the contactor control circuitry 40/40′ to activate the contactor coil 44 to connect the vehicle electrical system to the remote or shore AC power supply. Alternatively, an automatic reset can be incorporated into the MCU in which the status of the electrical system is periodically monitored by the MCU and power to the vehicle is restored when all when all fault conditions have been eliminated.

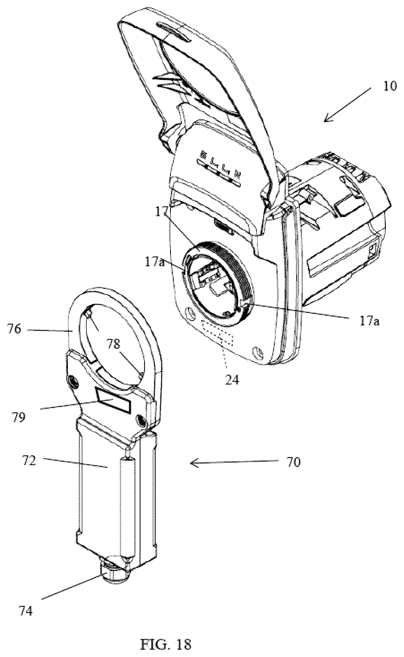

The device 10 can be configured for a hi-pot test bypass that will allow the device itself to be tested within the vehicle electrical system. The object of the hi-pot test is to verify that there is no electrical connection from L1, L2 and Neutral to GND on the vehicle. The hi-pot test is performed by the OEM of a vehicle or a repair shop performing electrical repairs to the vehicle. To perform the hi-pot test, the L1, L2 and Neutral lines are all connected together at a junction and a high voltage AC or DC signal is injected between the junction connection and ground. If the vehicle electrical system is sound, very little or no current will flow through the circuit. Since the ground monitoring interrupter device 10 requires continuity between GND and Neutral to measure voltage and impedance, performing the hi-pot test is problematic. Thus, in one feature, the device 10 includes a ground isolation circuit 50 shown in FIG. 17 that is incorporated into the power input circuitry 35 of the device before the AC_GROUND input.. An AC_GND ISOLATION signal is generated by the MCU 26 when the device is placed in “factory mode” in order to run the test. The “factory mode” can be entered using a physical key for the device, by special cables used to plug into the vehicle electrical system, or as a default condition when the device is first produced. In the “factory mode”, the contactor coil 44 is not energized and the contactor is held in a closed state with a mechanical device. The AC_GND ISOLATION signal activates the relay in the ground isolation circuit 50 to ensure that the GND connection is open and that there is no continuity between the AC_GND_IN signal and the AC ground input to the MCU and other circuitry of the device. It is noted that the relay in the circuit 50 can be normally open or normally closed. In the latter case, the device 10 requires external power during the hi-pot test.

With the device in the factory mode, a separate hi-pot testing device can be connected to the device 10 to conduct the hi-pot test. Once the testing is complete, the MCU 26 is placed in the “run” mode which de-activates the device holding the contactor closed and activates the circuitry 25/25′, 30/30′, 35 and 40/40′. The MCU is configured to communicate with the separate hi-pot testing device to determine if the test was conducted and was successful. The MCU can be further configured to set a hi-pot test indicator to a predetermined value indicative of successful completion of the hi-pot test, such as a “1” for a successful completion versus a “0” for no hi-pot test or a failed hi-pot test. This hi-pot test value is stored for access by thee MCU when the device 10 is attempted to be operated to provide power to the RV. In that case, the MCU is configured to canvas the stored value and to prevent operation if the stored value is not properly set (i.e., a “1” value), indicating that the test was failed or was never run. In one embodiment, the MCU can prevent transmission of the CONTACTOR_CTRL signal to the contactor control circuit 41 to prevent the contactor from being closed.

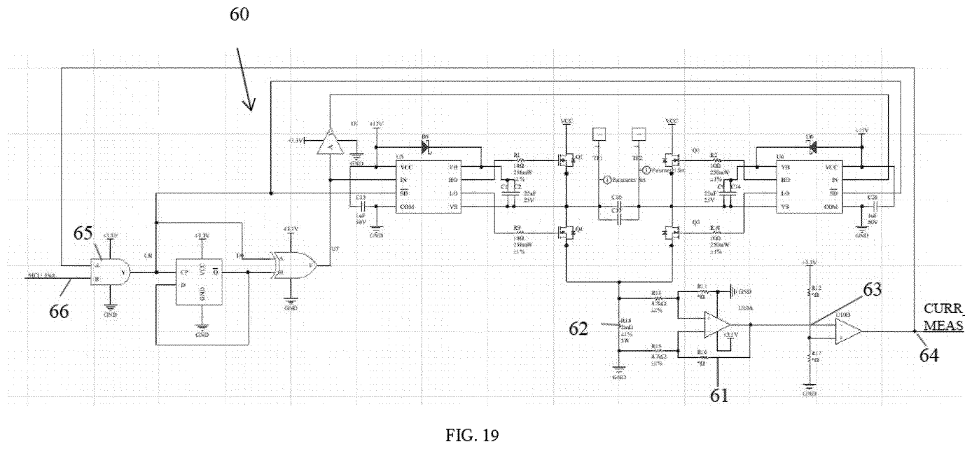

In one embodiment, in preparation for the hi-pot test a separate hi-pot power device 70, shown in FIG. 18, that can be mated with the GMI device 10 to be tested. The device 70 includes a body 72 that includes a circuit board incorporating an inductive ring 79 and associated power circuitry for the device. The circuit board also includes a microcontroller or microprocessor for monitoring and controlling the inductive power generated by the inductive ring 79 of the device 70. An electrical cable fitting 74 is provided to receive an electrical cable for connection to a power supply. The body includes a mounting ring 76 that is sized to fit around the receptacle 17 of the GMI device 10, with tabs 78 that are seated within notches 17a in the receptacle to orient the hi-pot power device 70 on the GMI device. In particular, the tabs interlock with the notches to orient the inductive ring 79 directly beneath the receptacle and in alignment with a corresponding receiving coil 24 in the GMI device 10. The receiving coil 24 of the GMI device powers a 24V circuit in the GMI device that is then regulated to an appropriate voltage to power the MCU 26. This allows the MCU to control the ground isolation circuit 50 (FIG. 17) as described above.

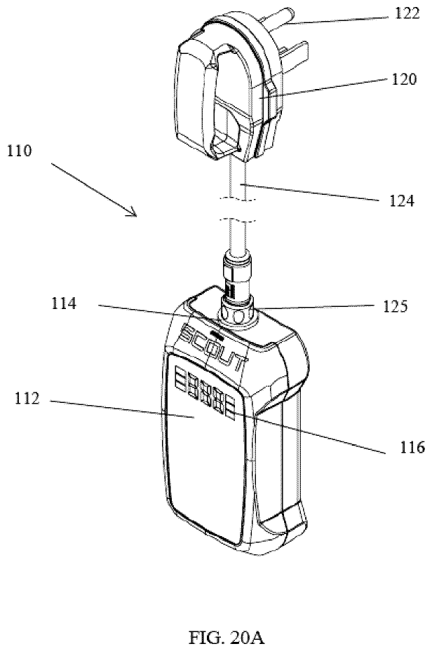

The circuit board of the hi-pot power device includes a driving circuit 60 shown in FIG. 19 for controlling the current driving the inductive ring 79. In one embodiment, the current output of the circuit, CURR_MEAS, is constantly compared by the microcontroller of the device 70 to a set point. In the event the current flowing through the inductive ring exceeds the set point, the circuit will automatically modulate a PWM drive signal driving the inductive ring in order to keep the current at or below the set point. This is done by using an op-amp 61 to compare the voltage across a current-sense resistor 62 to a voltage set by a resistor divider 63. The output 64 of this op-amp enters an AND gate 65 with the drive PWM signal 66 to cut off the drive signal if necessary.

The circuit board and microprocessor of the hi-pot power device also includes a wireless communication component that provides wireless communication to the MCU of the GMI device 10. The wireless communication component can also communicate with the MCU 26 of the GMI device 10 to enable or disable features of the device 10 as desired by the OEM or repair technician. These features can include activating an audible alarm when electrical issues are detected and over and/or under voltage detection. The wireless hi-pot testing device can include its own microcontroller and memory to receive and store data transmitted by the GMI device 10, and/or to store and transmit data to the MCU of the GMI device, such as settings for operation of the device.

The device 10 is provided with a visual display 14, controlled by the MCU 26, that can provide an immediate indication of the status of the power supplied to the vehicle through the device. In addition, the device can communicate with a display onboard the vehicle or with a remote device, such as a smart phone.

In the illustrated embodiment, the MCU 26 is incorporated into the device 10 that interfaces between the external remote or shore AC power supply and the vehicle electrical system. Alternatively, the MCU can be incorporated into the vehicle electrical system, such as before the primary fuse/circuit breaker panel. The MCU can be provided as a plug-in module or as a fixed component within the electrical system. The monitoring circuitry would remain in the device 10. The MCU 26 may be provided with data storage and data communication capabilities that can store and/or communicate information when a fault condition is detected, either when the device 10 is first connected to an AC power supply, or while power is being supplied to the vehicle electrical system. Since the device 10 is continuously monitoring the AC power supply, the MCU can also calculate usage data that can be stored and/or transmitted. As noted, the device 10 can include a wireless communication capability that allows the MCU 26 of the device to communicate to separate external device. In some embodiments, the device can communicate information to a remote display, such as a dashboard screen, hand-held device or smart phone. The information can include the current status of the GMI device and the vehicle electrical system, triggering events and the like. The wireless communication can also be configured to receive signals form the remote device to, for instance, remotely reset the GMI device 10 after the occurrence of an event.

In the illustrated embodiment, the ground monitoring interrupter device 10 is integrated into the vehicle electrical system. Thus, in lieu of a conventional power inlet on the RV or boat, the ground monitoring interrupter device can provide the power inlet, combining access to external AC power with monitoring functions. In another embodiment, the device 10 can be combined with a retractable cable reel that is directly connected to the vehicle electrical input at all times. The cable can be deployed for connection to an AC power pedestal and retracted using the vehicles 12V system.

The GMI device 10 can be provided with a tamper detection or tamper prevention feature. In the event that the ground monitoring interrupter device 10 is removed or bypassed in the vehicle electrical system, the device can be configured to detect and record the event and/or to transmit an alarm, and/or to disable the vehicle interface to the offshore/remote AC power supply. In one embodiment, the device is configured to measure current at two points in the electrical array, with one point in the device and the other point in the vehicle electrical system. A discrepancy in current measurements is indicative of tampering or bypassing the GMI device 10. In another embodiment, the device generates a high frequency pulse on one of the AC input lines to the device. A separate downstream device in the vehicle electrical system looks for the pulse and identifies tampering if the pulse is not detected by the downstream device. A third embodiment includes a mechanical latching element internal to the GMI device 10 that trips if the device is removed improperly, rendering the device non-functional. The MCU of the device can be configured to require a key signal before the device can be physically removed from connection to the vehicle electrical system. If the key signal has not been received by the MCU, and the device is improperly disconnected, the MCU can send an activation signal to the mechanical latching element such as a spring-loaded connector, to disable the device.

The ground monitoring interrupter device 10 of the present disclosure can be provided in different packages. In one variation, the contactor 43 and coil 44 can be incorporated into the device 10 or can be mounted remotely. In the latter case, the remotely connected contactor can be provided with a wired or a wireless connection to the RV power input to enable or disable the connection to the vehicle. In another variation, the primary electronics, including the MCU 26 can be integrated into the vehicle itself, plugging into the primary fuse/circuit breaker. The hand-held version described above can be primarily used to verify that the electrical interface at a campground are ready for connection to the device 10 when connected to the RV electrical system. The hand-held version is primarily configured to look for over/under voltage, improper wiring and ground impedance. In a further version, the device 10 can be combined with a cable reel with a retractable cable. The cable is directly connected to the vehicle at all times and can be deployed to connect to a pedestal. The cable can be retracted using a 12V powered system.

It is noted that the circuitry and description are generally directed to a 50 Amp/240V vehicle electrical system. The device 10 can be modified for a 30 Amp/120V system having a single line voltage L1 input.

It is contemplated that the MCU 26 of the ground interrupter device 10 includes a memory that allows operating parameters and data to be stored. The operating parameters can be used to set conditions for electrical fault and for device reset. The MCU can also incorporate wireless transmission capabilities for reception of operating parameters from a remote device and for transmission of data to the remote device.

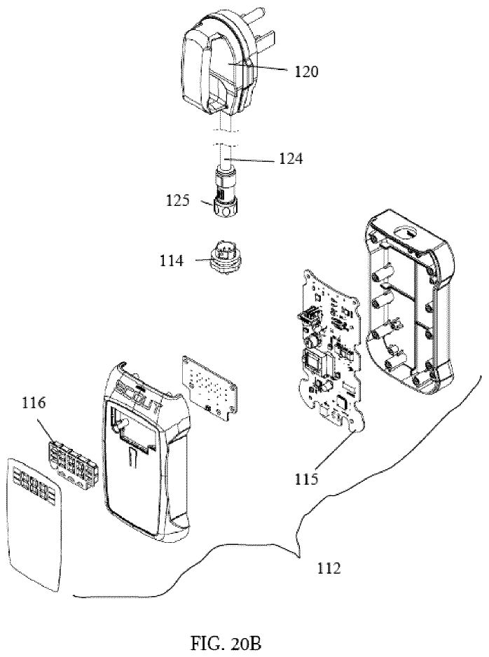

In another embodiment, aspects of the ground monitoring interrupter device 10 can be implemented in a hand-held device 110, shown in FIG. 20A, that can be plugged into the power supply or shore-power to evaluate the integrity of the electrical signal before the RV is connected to the power supply/shore-power pedestal. The device 110 is similar to the device 10 but it does not include a wire termination module 12, contactor components 42, 44 or the associated circuitry. The device 110 includes a base 112 and a replaceable tester cable 120. The tester cable 120 includes a plug component 122 that can be provided in different configurations for mating with differently configured sockets at the power supply/shore-power pedestal. By way of example, the plug component can be NEMA 5-15P, NEMA TT-30P or NEMA 14-50P. The plug component is connected to a cable 124 with a terminating fitting 125 that is configure to engage a mating fitting 114 on the base 112. In one embodiment, the fittings 114, 125 can be quick-connect fittings for electrically connecting the tester cable 120 to the base 112. The hand-held device 110 incorporates much of the same circuitry as the device 10, excluding the contactor circuitry. In particular, the hand-held device 110 includes a circuit board 115 that includes the circuitry 32′ shown in FIG. 8 to measure the voltage at the power supply, the circuitry 31″′ shown in FIG. 11 to apply a sine wave signal to the ground line, the circuitry 30″′ of FIG. 12 for measuring the ground impedance, and a microcontroller, similar to the MCU 26. It can be appreciated that the MCU in the hand-held device 110 is configured and operable to assess the voltage measured by the circuitry 32′ and determine whether the ground impedance measured by the circuitry 30″′ is above the required threshold discussed above. If the measured ground impedance falls below the required threshold, the MCU of the hand-held device provides an indication on the display 116 that the power supply/pedestal has failed the ground fault test. The visual display can be accompanied by an audible alarm.

The hand-held device 110 can incorporate a cable identification feature that can allow the hand-held device to determine which metrics need to be displayed and/or tested to verify the wiring associated with the plug-in location. For instance, each tester cable 120 that would be connected to the device has a resistor that is specific to the plug style for the plug being tested. For instance, a 240V split-phase plug (NEMA 5-15P) has a 50Ω resistor, a 120V/30 A plug (NEMA TT-30P) has a 100Ω and a 120V/15 A plug (NEMA 14-50P) has a 150Ω resistor, each of which can be detected by circuitry in the base 112 of the hand-held device 110. In another approach, a single cable can be provided with a selectable plug/resistor combination that can be selected by toggling between plug configurations.

What is claimed is:

1. A ground monitoring device for determining ground fault conditions in an external AC power supply having L1 and/or L2, ground and neutral lines, the device comprising:
a housing including;
electrical contacts for direct electrical connection to L1 and/or L2, AC Ground and AC Neutral lines of the external AC power supply;
a printed circuit board (PCB) connected to the electrical contacts and including ground impedance measurement circuitry and a microprocessor control unit (MCU); and
a display connected to the PCB,
wherein the ground impedance measurement circuitry is connected to the AC ground line and to the AC neutral line and is configured to measure the impedance of the AC ground line; and
wherein the MCU is configured and operable to compare the impedance measured by the ground impedance measurement circuitry to a predetermined impedance value indicative of a desired ground impedance, and to generate an indication on said display if the impedance measured by the ground impedance measurement circuitry is below the predetermined value.

2. The ground monitoring device of claim 1, further comprising:
an electrical power receptacle configured to engage a power cable connected to the external AC power supply the power receptacle including a connector array with the contacts for direct electrical connection to L1 and/or L2, AC Ground and AC Neutral lines of the AC power supply;
a wire termination module including a contactor connected to an electrical system of a vehicle that can be energized to close the contactor to electrically connect the device to the electrical system of the vehicle and de-energized to open the contactor to interrupt the electrical connection to the electrical system of the vehicle; and
the PCB includes a contactor control circuitry that is connected to the contactor coil and is configured to energize the contactor only upon receipt of a contactor control signal from said MCU and to de-energize the contactor when the contactor control signal is not received,
wherein the MCU is configured and operable to generate the contactor control signal only if the impedance measured by the ground impedance measurement circuitry is below the predetermined value.

3. The ground monitoring device of claim 1, wherein said ground impedance measurement circuitry includes:
a first circuit to apply an AC signal to the AC ground line, the AC signal controlled by the MCU, and
a second circuit to compare an electrical signal in the AC ground line with the electrical signal in the AC neutral line, in which an output of the second circuit constitutes the impedance measured by the ground impedance measurement circuitry provided to the MCU.

4. The ground monitoring device of claim 1, wherein said MCU is operable to:
determine the frequency of all other AC signals imposed on the AC ground line by all other ground monitoring interrupter devices; and
set the frequency of the AC signal applied to the AC ground line to a frequency different from the frequency of said all other AC signal.

5. The ground monitoring device of claim 4, wherein MCU is configured to obtain the magnitude of the frequency of said all other AC signals and apply a fast Fourier transform or Goertzel filter function to determine the magnitude of the frequency of the AC signal set by the MCU.

6. The ground monitoring device of claim 3, wherein:
the first circuit and MCU are configured to generate a composite signal for the AC signal applied to the AC ground line, which is a composite of three AC signals having different, non-harmonic frequencies.

7. The ground monitoring device of claim 6, wherein:
the MCU is configured to multiply the applied AC signal and the output of the second circuit for each of the three frequencies and solve the equation |Z|=\sqrt{R²+(X_{L}−X_{c})²}, where Z is the total impedance common to all frequencies, R is the actual resistance, X_{c} is the capacitance component 1/jωC for each frequency and X_{L} is the inductance component jωL for each frequency, for the actual resistance R; and
the MCU compares the actual resistance to the predetermined impedance value and generates the contactor control signal only if the output of the actual resistance is below the predetermined value.

8. The ground monitoring device of claim 2, wherein:
said MCU is configured to generate a pulse signal at a frequency; and
said contactor control circuitry receives said pulse signal and is configured to energize the contactor coil only if the frequency of said pulse signal is at a pre-determined frequency.

9. The ground monitoring device of claim 2, wherein the PCB further includes power input circuitry connected to the electrical power receptacle and configured to provide AC power to the device only when the AC wiring is correct.

10. The ground monitoring device of claim 3, wherein said MCU is configured to compare the output of the second circuit of the ground impedance measurement circuitry to the impedance predetermined value at a predetermined time interval when the device is connected to the external AC power supply.

11. The ground monitoring device of claim 10, wherein the predetermined time interval is shorter when the device is first connected to the external AC power supply, and longer after a predetermined time delay.

12. The ground monitoring device of claim 11, wherein the shorter time interval is 50 ms, the longer time interval is 150 ms.

13. The ground monitoring device of claim 2, further comprising a ground isolation circuit interposed in the direct electrical connection between the device and the AC Ground line of the AC power supply, the ground isolation circuit including a relay that in an open state breaks the direct electrical connection between the device and the AC Ground line and in a closed state maintains said direct connection, the relay operable to enter the open state upon receipt of a ground isolation signal from the MCU upon entering a factory mode for the device.

14. The ground monitoring device of claim 13, wherein said MCU is further configured:
to activate the ground isolation circuit in response to connection with a separate high potential (hi-pot) testing device;
to set a stored hi-pot test indicator to a value in response to a signal received from the testing device that the hi-pot test was successfully completed by the ground monitoring device;
to poll the stored hi-pot test indicator when the interrupter device connected to the AC power supply; and
to generate the contactor control signal only if the hi-pot test indicator has the value indicative of successful completion of the hi-pot test by the device.

15. The ground monitoring device of claim 13, further comprising a separate power device including an inductive ring connectable to an external electrical power supply and configured to provide inductive power to said ground monitoring device to activate the ground isolation circuit.

16. The ground monitoring device of claim 15, wherein:
the housing of the ground monitoring device includes an electrical power receptacle configured to engage a power cable connected to the external AC power supply; and
the separate power device includes a mounting ring configured to be seated around said receptacle,
wherein the electrical power receptacle and the mounting ring include an interlocking tab and notch arrangement to orient the power device relative to the housing.

17. The ground monitoring device of claim 15, wherein:
the PCB of the ground monitoring device includes a memory that allows operating parameters and data to be accessed and stored by the MCU;
the MCU of the ground monitoring device includes wireless transmission capabilities for reception of the operating parameters from a remote device and for transmission of the data to the remote device; and
the separate power device includes a microprocessor with wireless transmission capabilities configured for wireless communication with the MCU of the ground monitoring device.
